(19) United States
(12) Patent Application Publication
(10) Pub. No.: US 2026/0333646 A1
(43) Pub. Date: Oct. 22, 2026

(54) VEHICLES AND ELECTRONIC ASSEMBLIES HAVING COOLING ASSEMBLIES WITH BLOCKING MECHANISMS FOR AIRFLOW REGULATION

(71) Applicant: Toyota Motor Engineering & Manufacturing North America, Inc., Plano, TX (US)

(72) Inventors: Ercan M. Dede, Ann Arbor, MI (US); Danny J. Lohan, West Bloomfield, MI (US); Shailesh N. Joshi, Ann Arbor, MI (US)

(73) Assignee: Toyota Motor Engineering & Manufacturing North America, Inc., Plano, TX (US)

(21) Appl. No.: 19/184,794

(22) Filed: Apr. 21, 2025

(51) Int. Cl. H05K 7/20

(52) U.S. Cl. CPC H05K 7/20854

(57) ABSTRACT

In one embodiment, a cooling assembly including a plate includes a surface and a plurality of openings; a plurality of angled fins extending from the plate, wherein the plurality of angled fins define a plurality of channels comprising converging channels and diverging channels; and one or more blocking mechanisms extending from the plate, the one or more blocking mechanisms configured to regulate airflow.

### BACKGROUND

Heat generating components, such as power electronic devices, may require removal of heat flux so that they operate below their maximum operating temperature. Cooling devices such as heat sinks may be used to transfer heat flux from a heat generating component to the ambient air. Convection may be used to force airflow through an array of fins of the heat sink. The array of fins increases the surface area that the airflow is exposed to, thereby increasing the transfer of heat to the airflow.

Vehicles, such as electric vehicles like automobiles, trucks, and aircraft, may include inverter circuits having power electronic devices that generated significant heat fluxes that should be removed. Movement of the vehicle through the environment creates a natural airflow around the vehicle as it travels. However, including fins of a heat sink on the body of the vehicle will increase drag on the vehicle, thereby lowering efficiency of the vehicle.

Accordingly, alternative cooling assemblies and improvements for cooling heat generating components may be desired.

### BRIEF SUMMARY

In one embodiment, a cooling assembly including a plate comprising a surface and a plurality of openings; a plurality of angled fins extending from the plate, wherein the plurality of angled fins define a plurality of channels comprising converging channels and diverging channels; and one or more blocking mechanisms extending from the plate, the one or more blocking mechanisms configured to regulate airflow.

In another embodiment, an electronic assembly includes a plate having a surface and a plurality of openings, a plurality of angled fins extending from the plate, wherein the plurality of angled fins define a plurality of channels comprising converging channels and diverging channels, and one or more blocking mechanisms extending from the plate, the one or more blocking mechanisms configured to regulate airflow.

In another embodiment, a vehicle includes a body and an electronic assembly coupled to the body. The electronic assembly includes a plate having a first surface, a second surface, and a plurality of openings, a plurality of angled fins extending from the first surface of the plate, wherein the plurality of angled fins define a plurality of channels comprising converging channels and diverging channels, one or more blocking mechanisms extending from the plate, the one or more blocking mechanisms configured to regulate airflow, and one or more electronic devices coupled to the second surface of the plate.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an isometric view of an example cooling assembly.

FIG. 2A illustrates a top view of an example cooling assembly according to one or more embodiments described and illustrated herein.

FIG. 2B illustrates a side-width view of an example cooling assembly according to one or more embodiments described and illustrated herein.

FIG. 2C illustrates a side-length view of an example cooling assembly according to one or more embodiments described and illustrated herein.

FIG. 3 illustrates a top view of an example cooling assembly with different individual blocking mechanism configurations and positions according to one or more embodiments described and illustrated herein.

FIG. 4 illustrates example blocking mechanisms in various individual configurations according to one or more embodiments described and illustrated herein.

FIGS. 5A-5D illustrates a top view of an example cooling assembly with various blocking mechanism groupings to produce different cooling effects according to one or more embodiments described and illustrated herein.

FIG. 6A illustrates a number of bar graphs that show airflow distribution of external and internal airflows from different blocking mechanism groupings according to one or more embodiments described and illustrated herein.

FIG. 6B illustrates a line graph that illustrates different airflow configurations in different modes of a vehicle operation according to one or more embodiments described and illustrated herein.

FIG. 7 illustrates an example vehicle having a plurality of cooling assemblies according to one or more embodiments described and illustrated herein.

### DETAILED DESCRIPTION

Embodiments of the present disclosure regulate airflow entering a heat sink that is utilized to cool heat generating components by deploying activatable blocking mechanisms positioned amongst external converging and diverging fins (external fins) above the heat sink. The converging and diverging fins thus form converging and diverging channels (external channels) and create a pressure differential to cause some airflow to enter the heat sink below a plate surface, furthermore, blocking mechanisms are positioned amongst the external fins in a cooling assembly and block and redirect air to the heat sink so that it may receive additional cooling airflow. The cooling assemblies described herein have a low pressure drop by utilizing angled fins to produce a pressure difference between alternating converging channels and diverging channels. More particularly, ambient air approaches the angled fins and is allowed to flow through the converging and diverging channels (collectively and interchangeable referred to herein as external channels). The converging channels create regions of high pressure, while the diverging channels create regions of low air pressure. These regions of high and low air pressure are fluidly coupled to an internal heat sink comprising an array of internal fins that define an array of internal channels. The pressure difference is leveraged to pump a fraction of air into the internal channels. This is reinforced by activatable blocking mechanisms placed among and around the external channels that further redirect and increase pressured airflow into the internal channels. This redirected air travels within the internal channels from one part of the external channels and then exits at another part of the external channels. The redirected air is brought in close proximity to the heat generating components that are to be cooled such that the redirected air is warmed up, thereby extracting heat from the internal fins. The warmed redirected air then exits the internal heat sink on another side of the external channels where it joins the freestream of air that flows through the diverging channel and exits at the backside of the cooling assembly.

When embedded in the surface of a body (e.g., a vehicle) and exposed to airflow (either from a fan or from movement of the body itself), the cooling assemblies of the present disclosure utilize a novel, streamlined external manifold that directs airflow, facilitated by blocking mechanisms, to the internal heat sink that is “hidden” from the external flow, and removes the need to the entire heat sink to be directly exposed to the external airflow, which would increase drag on the system.

Various embodiments of cooling assemblies are described in detail below.

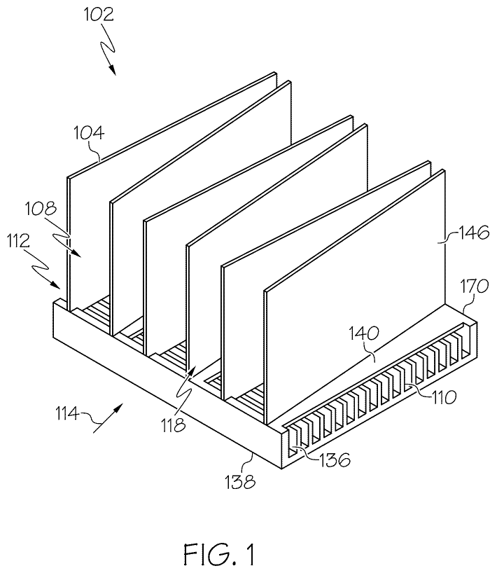

Referring now to FIG. 1, an example cooling assembly 102 is illustrated in an isometric view. The example cooling assembly 102 represents designs of cooling assemblies utilizing converging and diverging fins without a blocking mechanism disclosed in U.S. patent application Ser. No. 18/905,758, incorporated herein by reference in its entirety. The example cooling assembly 102 includes a plate 112 having an array of internal fins 110. The internal fins 110 may be parallel to one another and extend along one axis. In other embodiments, the internal fins 110 may not run parallel to one another. The array of internal fins 110 define an array of internal channels 136 through which redirects air 116 travels, as described in more detail below.

The plate 112 has a heat receiving surface 138 and a cooling surface 140 The array of internal fins 110 extend between the heat receiving surface 138 and the cooling surface 140. Thus, the array of internal channels 136 is disposed between the heat receiving surface 138 and the cooling surface 140.

The heat receiving surface 138 is configured to be coupled to one or more heat generating components (not shown). The heat generating components are thermally coupled to the heat receiving surface 138. The cooling surface 140 of the plate 112 is opposite from the heat receiving surface 138 and is operable to receive air 114 that is generated by one or more fans or propellers (not shown) or by movement of the example cooling assembly 102 through the environment.

The example cooling assembly 102 further includes a plurality of angled fins 104 that extends from the cooling surface 140. The angled fins 104 are angled such that they are non-orthogonal with respect to an exit edge of the plate. The angled fins 104 define alternating converging channels 108 and diverging channels 118. Thus, the converging channel 108 is adjacent to a diverging channel 118. In the converging channels 108 the distance between the two angled fins 104 decrease in a direction of the air 114. In the diverging channels 118 the distance between the two angled fins 104 increases in a direction of the air 114. An individual angled fin may define both a converging channel 108 and a diverging channel 118.

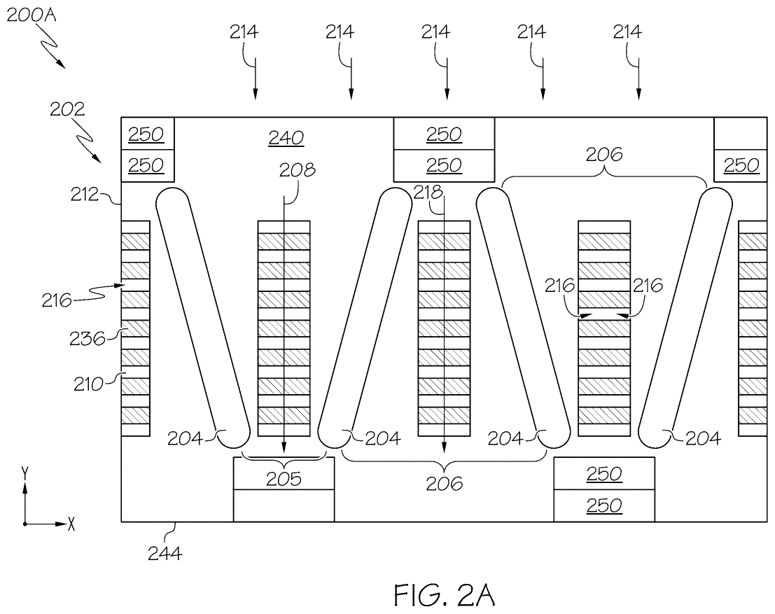

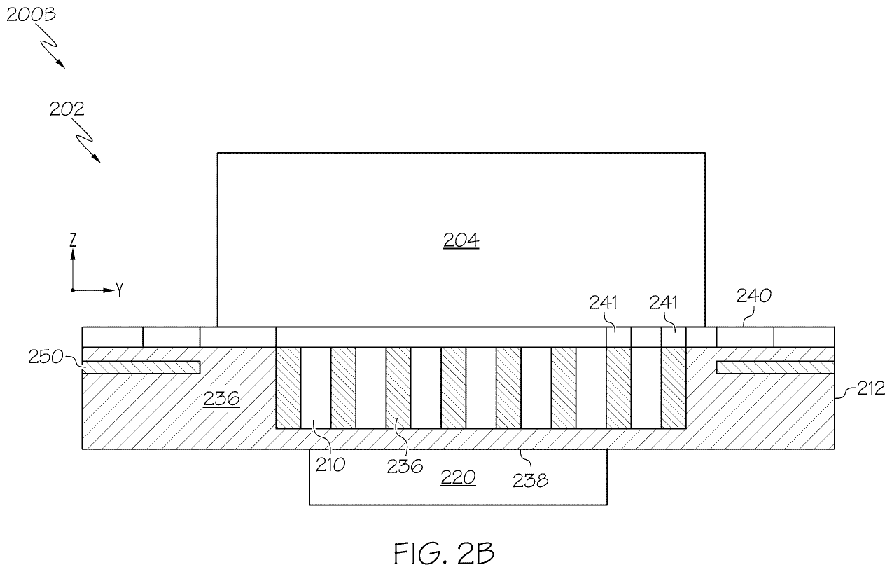

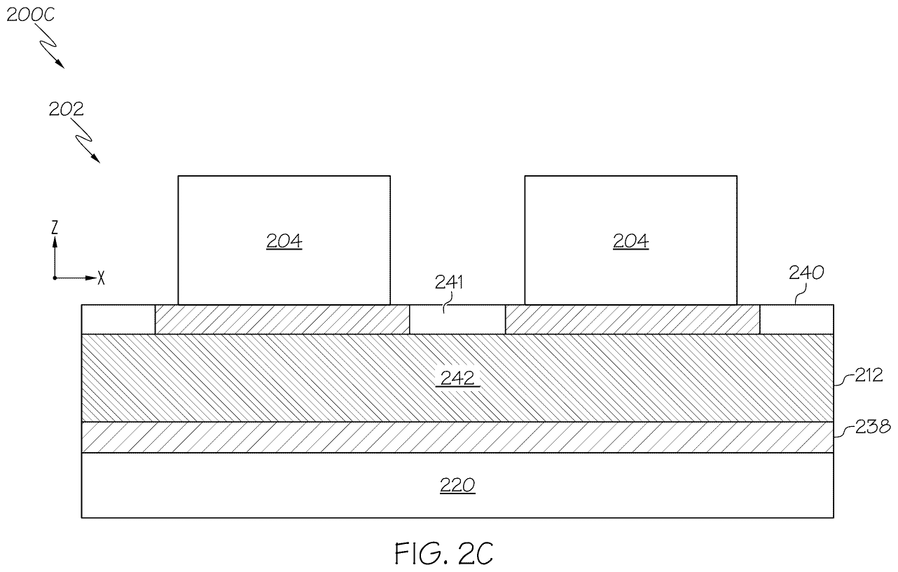

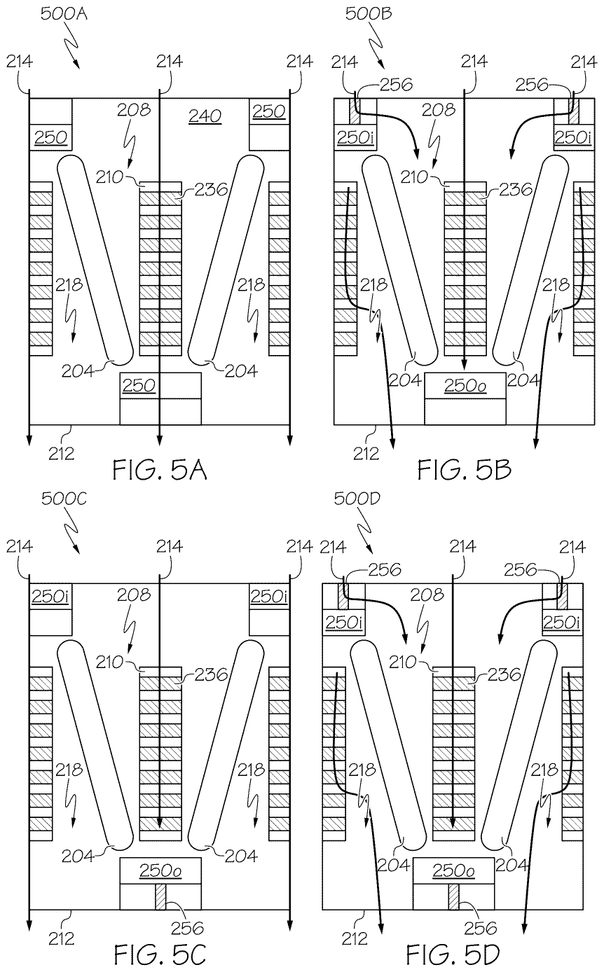

FIG. 2A illustrates a top view 200A of a cooling assembly 202 according to one or more embodiments described and illustrated herein. The cooling assembly 202, may be a component of an electronic assembly. The cooling assembly 202 may include one or more of the features and components of the cooling assembly 102 of FIG. 1 as described above and may have a similar structure and layout of one or more of the features and components described herein. The cooling assembly 202 includes a plate 212 having an array of internal fins 210. The internal fins 210 may be parallel to one another and extend along one axis. In other embodiments, the internal fins 210 may not run parallel to one another. The array of internal fins 210 define an array of internal channels 236 through which redirected air 214 travels, as described in more detail below with reference to FIGS. 5A-5C. In other embodiments, the internal fins 210 may not run parallel to one another. The array of internal fins 210 define an array of internal channels 236 through which redirected air 216 travels, as described in more detail below.

The cooling assembly 202 further includes a plurality of angled fins 204 that extends from the cooling surface 240 (also referred to herein as a first surface). The angled fins 204 are angled such that they are non-orthogonal with respect to an exit edge 244 of the plate. The angled fins 204 define alternating converging channels 208 and diverging channels 218 (external channels). Thus, a converging channel 208 is adjacent to a diverging channel 218. In the converging channels 208 the distance between the two angled fins 204 decrease in a direction of the air 214. In the diverging channels 218 the distance between the two angled fins 204 increases in a direction of the air 214. An individual angled fin 204 may define both a converging channel 208 and a diverging channel 218. The angled fins 204 are made of a thermally conductive material and may have any height. As non-limiting examples, the angled fins 204 may be made of aluminum or copper.

Unlike the cooling assembly 102 of FIG. 1, the cooling assembly 202 includes one or more blocking mechanisms 250. The blocking mechanisms 250 may be placed on the cooling surface 240 at various locations on the plate 212. For example, in some embodiments, one or more blocking mechanisms 250, may be placed at converging ends 205 of two angled fins 204, e.g., at the narrowest point of a converging channel 208, formed by the two angled fins 204. In some embodiments, one or more blocking mechanisms 250 may be placed at diverging ends 206 formed by two angled fins 204, e.g., at the widest point of a diverging channel 218 formed by the two angled fins 204. An electronic control unit (ECU) may control one or more of the blocking mechanisms 250, for example to activate or deactivate one or more available blocking mechanisms 250 or different combinations thereof. The ECU may include processor(s) that are generally configured to retrieve and execute instructions stored in one or more memories, including local memories like computer-readable medium, as well as remote memories and data stores. Similarly, processor(s) are configured to store application data residing in local memories like the computer-readable medium, as well as remote memories and data stores. In certain embodiments, processor(s) are representative of a one or more central processing units (CPUs), graphics processing unit (GPUs), tensor processing unit (TPUs), accelerators, and other processing devices. For example, an ECU may control a blocking mechanism to activate at 70%, where it is partially elevated or positioned to block at only 70% of its air blocking capacity.

In some embodiments, the air 214 flows through both the converging channels 208 and the diverging channels 218. The flow of air 214 may be generated by fans, propellers or other devices. The flow of air 214 may also generated by the cooling assembly 202 moving through the environment. As a non-limiting example, the cooling assembly 202 may be attached to a component of a moving vehicle, such as a car, a plane, or a vertical take-off and landing vehicle (VTOL). The air 214 moves through the converging channels 208 and diverging channels 218 and then past the cooling assembly 202.

Gaps between the adjacent angled fins 204 allow the air 214 to flow within both the converging channels 208 and the diverging channels 218. Because there are gaps between the adjacent angled fins 204, air 214 is not forced into the internal channels 236 by blocking the exit of the converging channels 208. Rather, air flows through the converging channels 208 and exit on the other side of the cooling assembly 202. However, the approaching air experiences a higher flow resistance in the converging channels 208 than the diverging channels 218 due to the converging shape. This causes some of the approaching air to bypass the converging channels 208 and instead flow within the diverging channels 218 that have a lower flow resistance. This redistribution of airflow causes a locally lower flow rate and higher static pressure in the converging channels 208, and a locally higher flow rate and lower static pressure in the diverging channels 218. In total, this causes a significant pressure difference between adjacent converging channels 208 and diverging channels 218.

The cooling surface 240 of the plate 212 exposes the array of internal channels 236 by way of openings within the converging channels 208 and the diverging channels 218. In some embodiments, the array of internal channels 236 may be exposed by full openings within the converging channels 208 and partially exposed by partial openings within the diverging channels 218. Thus, the internal channels 236 are partially blocked by the cooling surface 240 of the plate 212. In some embodiments, the partial openings are rectangular in shape but embodiments are not limited thereto. The full openings within the diverging channels 218 encourage air 214 to enter the internal channels 236 of the plate 212.

The converging channels 208 and the diverging channels 218 act primarily as a manifold and use the pressure difference created between the converging channels 208 and the diverging channels 218 to “pump” a fraction of the air 214 into the internal channels 236 within the plate 212. The mechanism used to create the pressure difference to pump air into the internal heat sink is based on Bernoulli's Principle, which states that increasing a fluid's velocity decreases its static pressure, while decreasing its velocity has the opposite effect.

For example, a fraction of the incoming air passes through the diverging channels 218 and a fraction of the incoming air 214 passes through the converging channels 208. Due to the pressure differential, a fraction of the air 214 passing into the internal channels 236 of the plate 212. The converging channel 208 creates a higher flow resistance than the diverging channel 218. This slows the air in the converging channel 208 and causes some air to bypass the converging channel 208 and enter the diverging channel 218 instead. This redistribution of air at the inlet of the manifold reduces the flow velocity of air in the converging channel 208, and increases the flow of velocity in the diverging channel 218. This has the effect of increasing the static pressure in the converging channel 208 region, while lowing the static pressure in the diverging channel 218 region. Thus, a significant pressure differential between the converging channels 208 and the diverging channels 218 is created that can be exploited to pump some fraction of air through the internal channels 236.

In addition to this effect, blocking mechanisms 250 are placed to redirect the air 214 flowing into the external channels 208 or 218 or onto the blocking mechanism 250 into the openings to enter the array of internal channels 236. Thus, blocking mechanisms 250 increase air flow into the array of internal channels 236 and increase the cooling of the internal heat sink as compared to a configuration where the blocking mechanisms 250 are inactivated or absent.

In some embodiments, redirected air within a converging channel 208 is directed downward into the array of internal channels 236 and past the internal fins 210, where it receives heat flux from one or more heat generating components 220 (e.g., power electronic devices). The redirected air then flows upward into a diverging channel 218 and may exit the cooling assembly 202.

Other internal fin configurations may also be provided. For example, the internal fins may be pin fins. The internal fins of the present disclosure may also be porous, which increases the surface area through which the redirected air travels through the internal channels.

Now turning to FIGS. 2B and 2C which illustrate a side-width view 200B of the example cooling assembly 202 and a side-length view 200C of the example cooling assembly 202, respectively, the plate 212 is shown with the heat receiving surface 238 (also referred to herein as a second surface) and the cooling surface 240.

The array of internal fins 210 extend between the heat receiving surface 238 and the cooling surface 240. Thus, the array of internal channels 236 is disposed between the heat receiving surface 238 and the cooling surface 240. The height of the array of internal fins 210, and therefore the distance between the heat receiving surface 238 and the cooling surface 240, is not limited by this disclosure and may depend on the particular application.

The plate 212 may be fabricated from any suitable thermally conductive material, such as, without limitation, aluminum and copper. The heat receiving surface 238 is configured to be coupled to one or more heat generating components, such as heat generating component 220 shown in FIGS. 2B-2C. It should be understood that one or more heat generating components may be used. The heat generating components are thermally coupled to the heat receiving surface 238 by any suitable means, such as, without limitation, by thermal paste, soldering, sintering, or brazing.

The heat generating component(s) may be any component in need of cooling. As a non-limiting example, the heat generating components may be power electronic devices, such as power switching devices used in inverter circuits for use in electric vehicles. The power electronic devices may include, but are not limited to, insulated-gate bi-polar transistors (IGBTs), metal-oxide-semiconductor field-effect transistors (MOSFETs), power transistors, and power diodes.

The cooling surface 240 of the plate 212 is opposite from the heat receiving surface 238 and is operable to receive the air 214 that is generated by one or more fans or propellers (not shown) or by movement of the cooling assembly 202 through the environment. The cooling surface 240 may include one or more openings 241 for airflow to allow air to enter the array of internal channels 236. FIG. 2C shows a closed end 242 of the plate 212.

In some embodiments, the blocking mechanism 250 may be positioned after the one or more openings 241 on the cooling surface 240, if there is space and when activated the blocking mechanism 250 blocks a portion of the channel 208, 218. Otherwise, the blocking mechanism 250 may be placed, or it may retreat within the one or more openings 241 (blocking several internal channels) when it is in an inactive state. For example, as seen in FIG. 2B, the blocking mechanism 250 is seen within an internal channel 236.

The blocking mechanisms 250 may be made of any suitable material including metallic alloys and plastics. The blocking mechanisms 250 may be activated when appropriate to block airflow between a set of fins 204 and increase the airflow to the array of internal channels 236. The blocking mechanisms may include and are not limited to four-bar and slider-crank mechanisms, and simple sliding, extending, or screw actuated mechanical components.

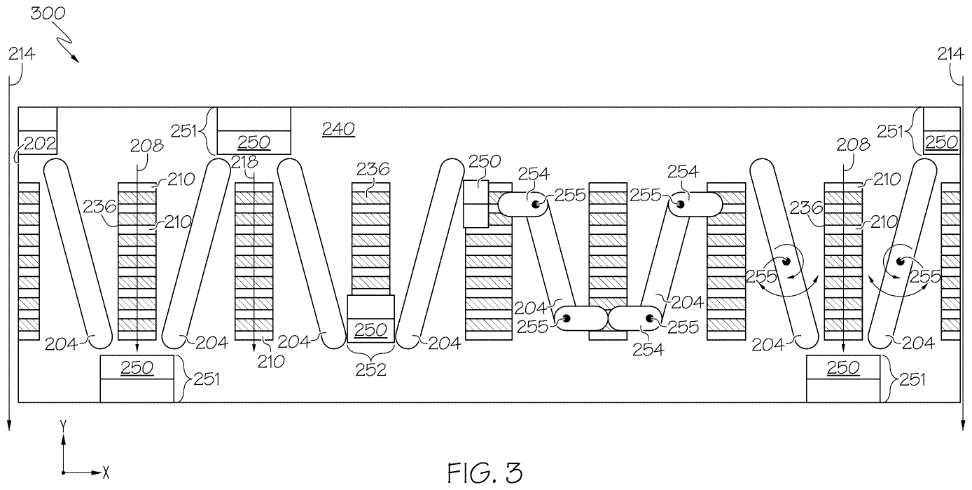

FIG. 3 illustrates a top view of an example 300 cooling assembly 202 with different example individual blocking mechanism configurations and positions according to one or more embodiments described and illustrated herein. The blocking mechanisms 250 may be placed on top of the cooling surface 240 of the plate 212.

As depicted in example 300, in some embodiments, the fin blocking mechanism 254 (shown as the second from the right example) may be constructed as part of the angled fins 204. The blocking mechanisms that are part of the angled fins 204 are referred to herein as fin blocking mechanisms 254. The ends of the angled fins 204 may be configured to or be capable of bending, e.g., by different connected links pivoting around a pivot point 255 when activated to block airflow from the air 214. It is to be understood that when referring to blocking mechanisms 250 herein, this refers to either one or both of the blocking mechanisms 250 or the fin blocking mechanisms 254, unless stated otherwise. In some embodiments, shown as the far-right example of FIG. 3, the angled fins 204 that utilize the fin blocking mechanisms 254 may have a pivot point 255 on a central location of the angled fin 204, to allow different portions of the angled fin 204 to be used as a blocking mechanism 254. In some embodiments there is only one pivot point 255, and in others multiple pivot points 255 may be placed on different locations on the angled fin 204 to produce different points where the angled fin may pivot and produce different portions capable of pivoting around the pivot point 255 that may be used as a blocking mechanism 254.

Activation of the blocking mechanisms may occur in several ways including by one or more motors or motor types such as a stepper motor, rotary motor, linear motor, other specialized motors, and the like. For example, an activation of the fin blocking mechanisms 254 may cause a motor to move the blocking mechanism 250 or a portion of the blocking mechanism 250 (e.g., a fin of the fin blocking mechanisms 254) into a position to block flow of the air 214. The movement and positioning may be in vertical or horizontal planes or axis. In some embodiments, the blocking mechanism 250 is placed outside of the external channels 208, 218 formed by two of the angled fins 204 in an external placement 251 in its inactivated state, e.g., at an outlet of the channels 208, 218.

In some embodiments, the blocking mechanism 250 is placed inside of or internal to the external channels 208, 218 in an internal placement 252 in its inactivated state, e.g., within the external channels 208, 218. Different blocking mechanisms may be of different sizes, for example, the blocking mechanism 250 placed in an internal placement 252 has to fit in a narrower section than the blocking mechanism 250 placed in an external placement 251 that can be larger since it does not have to conform to any spatial restrictions.

The blocking mechanism 250 may be used to partially or completely block the air 214 moving through the external channel, e.g., the channels 208 or 218, to redirect the airflow distribution of the air 214. The blocking mechanism 250 itself may be constructed in several ways. The blocking mechanism 250 may include a linear bearing mechanism with a lead screw to open and close a hinged flap. The blocking mechanism 250 may include an actuation mechanism that is electronic, hydraulic, or a shape memory alloy to move the mechanism from an activated or inactivated configuration.

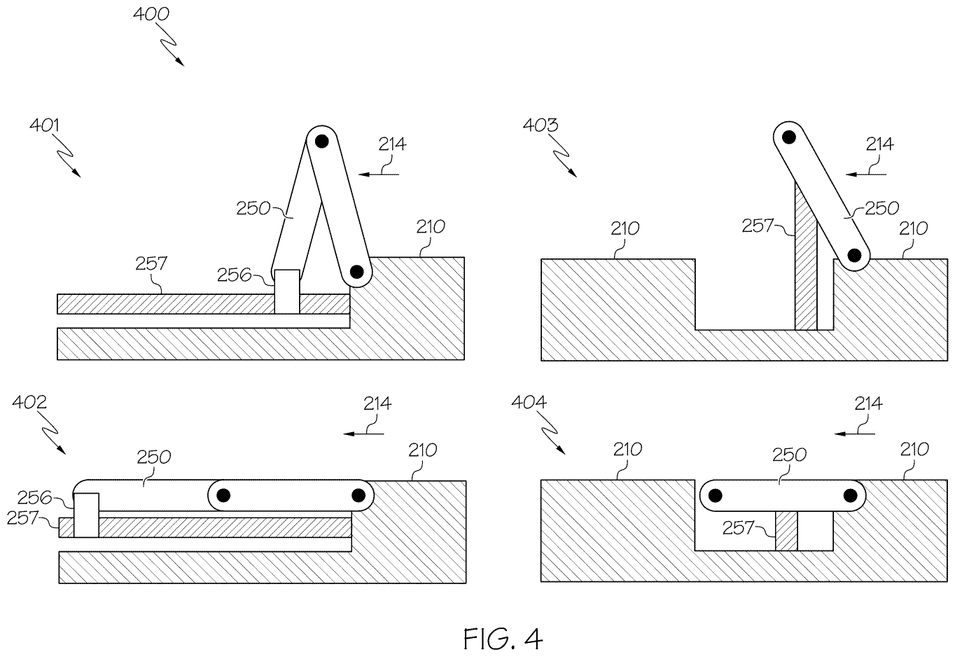

FIG. 4 illustrates blocking mechanisms 250 in various individual configurations 401-404 according to one or more embodiments described and illustrated herein. FIG. 4 is described in conjunction with FIGS. 1-3. Configuration 401 depicts a blocked configuration of the blocking mechanism 250 which may be entered into upon activating the blocking mechanism 250 to block and redirect the air on a cooling assembly 202. The blocking mechanism 250 may include two portions that fold upon each other upon activation into a blocked configuration. In some embodiments, the blocking mechanism 250 includes a slider mechanism 256 on an extending bar 257 positioned in an opening such as an opening 241 to the array of internal channels 236 between two internal fins 210. Upon activating the blocking mechanism 250, the slider mechanism 256 slides towards one of the internal fins 210 causing the blocking mechanism 250 to fold on itself and turn upwards to block or redirect incoming air 214. Upon deactivation, and as depicted in configuration 402, the blocking mechanism 250 may completely unfold and expand or spread into an open configuration within the opening 241 it is positioned in, e.g., an opening 241 to the array of internal channels 236, and in this configuration allows air to move through channels 208 or 218 between angled fins 204.

In some embodiments, the blocking mechanism 250 is made up of one piece that is nestled within an opening 241 when deactivated, e.g., as can be seen in configuration 404. The blocking mechanism 250 may be placed on a vertically extending bar 257, which extends and places the blocking mechanism 250 in a position to block the air 214 into a blocked configuration upon activation. The blocking mechanism 250 can be deactivated into an open configuration. When deactivated, the vertically extending bar 257 may shorten causing the blocking mechanism 250 to flatten within the opening 241 between the internal fins 210 and allow air through the external channels 208, 218.

FIGS. 5A-5D illustrate a top view of an example cooling assembly with various blocking mechanism groupings to produce different cooling effects according to one or more embodiments described and illustrated herein.

FIG. 5A depicts a bypass configuration 500A where the blocking mechanisms 250 are all inactive, and the air 214 is able to pass through the plate and the angled fins 204 without any obstructions. The air 214 may pass through openings on the cooling surface 240 into the internal channels 236 at a minimal rate.

When referring to blocking mechanisms 250 in different placements with regard to FIGS. 5B-5D, blocking mechanisms 250i refer to those that are placed to block inlets of the air 214, e.g., placed at inlets of the external channels 208, 218. Meanwhile, blocking mechanisms 250o refer to those blocking mechanisms 250 that are placed to block the air 214 coming out of outlets of the external channels 208, 218.

FIG. 5B depicts a blocked inlet configuration 500B where the blocking mechanisms 250i that are activated are at inlets of the external channels 208, 218 and are configured to block the air 214 entering the inlets of the external channels 208, 218. As can be seen, a slider mechanism 256 extends the activated blocking mechanisms 250 (vertically or horizontally) to block and redirect the air 214 into the channel between the angled fins 204, forcing more air into openings 241 to the internal channels 236 relative to the bypass configuration 500A.

FIG. 5C depicts a blocked outlet configuration 500C where the blocking mechanisms 250o that are activated are at outlets of the external channels 208, 218 and are configured to block the air 214 exiting out of the external channels 208, 218. As can be seen, a slider mechanism 256 extends the blocking mechanisms 250 at the outlet of the converging channel 208 to block and redirect the air 214 into the between the angled fins 204 into openings 241 leading into the array of internal channels 236 forcing more air into openings to the internal channels 236 relative to the configurations 500A and 500B. In some embodiments, the blocking mechanisms 250 are activated at the outlets of all external channels 208 and 218, while in others they are activated at the outlet for only one type of the external channels 208 and 218.

FIG. 5D depicts an internal flow configuration 500D that maximizes air flow in internal channels 236 by activating the blocking mechanisms 250i and 250o at both inlets and outlets of the external channels 208, 218. As can be seen, a slider mechanism 256 extends the blocking mechanisms 250 at the inlets and outlet of the external channels 208 and 218 to block and redirect all the air 214 into openings leading into the array of internal channels 236 forcing more air into the array of internal channels 236 relative to the configurations 500A, 500B, and 500C. Therefore, the cooling levels of 500D are higher than those of 500C, which in turn are higher than those of 500B, and in turn are higher than the cooling levels of 500A.

ECU(s) may be used to control one or more of the blocking mechanisms 250 to change the configuration of the cooling assembly to any of the configurations 500A, 500B, 500C and 500D.

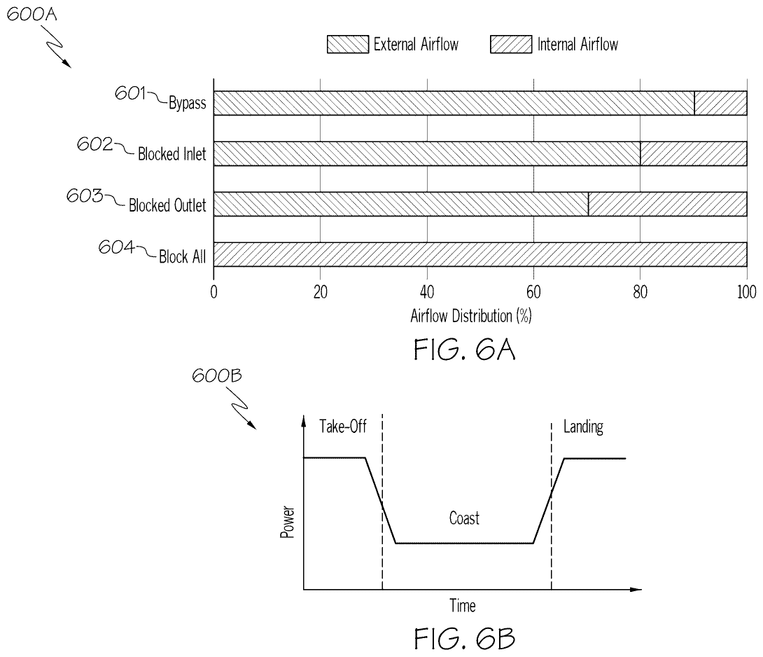

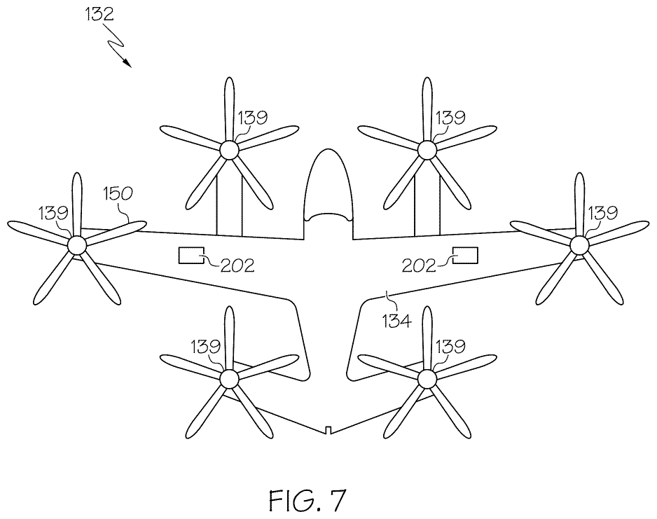

FIG. 6A illustrates several bar graphs 600A that depict airflow distribution between external and internal airflows for the different blocking mechanism grouping configurations 500A-500D of FIGS. 5A-5D. As is shown, the bypass configuration bar graph 601 corresponds to 500A of FIG. 5A and shows an 85-90% external air flow distribution and a 10-15% internal airflow distribution. The blocked inlet configuration bar graph 602 corresponding to 500B has an external airflow distribution of approximately 80% and an internal airflow distribution of approximately 20% and achieves a higher level of cooling than 500A. The blocked outlet configuration bar graph 603 which corresponds to 500C shows an external airflow of approximately 70% and an internal airflow of approximately 30%. The block all configuration bar graph 604 which corresponds to 500D shows an approximately 100% internal airflow distribution which may be suitable for high heat generation periods as it provides the highest level of cooling. The aforementioned percentages may fluctuate based on whether each blocking mechanism is deployed to partially or fully block air flow. For example, some the blocking mechanisms may be set to block at 50% capacity instead of at 100% capacity, where at 50% only a portion of the blocking mechanism may be elevated/exposed or used to block the air instead of the full surface of the blocking mechanism being used.

FIG. 6B illustrates a line graph that illustrates different airflow configurations in different modes of a vehicle operation according to one or more embodiments described and illustrated herein. The Y-axis 605 represents the power output of a vehicle (which positively correlates with heat generation) and the X-axis represents time. The power output increases in take-off and landing phases where the configurations of higher internal airflow (blocked outlet and the internal flow configurations 500C-500D are most suitable), where during a coasting phase with has a low power output and generates less heat, a bypass configuration 500A or blocked inlet configuration 500B with lower internal airflows and higher external airflows may be more suitable.

The cooling assemblies described herein may be incorporated into any device having heat generating components that should be cooled. Such devices include vehicles, such as the vehicle 132 illustrated in FIG. 7. The vehicle 132 of FIG. 7 is configured as an electric vertical take-off and landing aircraft (eVTOL). However, it should be understood that the vehicle 132 may take on other configurations, such as an airplane, an automobile, a truck, a train, a monorail, and the like. Any device where air flows by it may be configured to have the cooling assembly 202 as described herein. The vehicle 132 may have one or more cooling assemblies 202. As a non-limiting example, the cooling surface 140 may be flush with the surface of the body 134 the vehicle 132, such as the wing of the vehicle 132.

In the present example, airflow generated by the propellers 150 of the vehicle 132, as well as movement of the vehicle 132 through the atmosphere, passes into the manifold of the example cooling assemblies 202 defined by the angled fins 104. Because the angled fins 104 are arranged in the direction of the air 114, they produce a relatively low pressure drop across the example cooling assemblies 202. The internal fins 110 are below the surface of the body 134, and therefore only minimally contribute to drag on the vehicle 132.

In some embodiments, one or more cooling assemblies 202 are coupled to the vehicle 132 at one or more electric aircraft motors 139, such as at the nacelle of the electric aircraft motor 139 (e.g., the cowling component) where the power electronics are mounted internally and in close proximity to the electric machine of the electric aircraft motor 139. The cooling assemblies may be coupled to ECU(s) or processor(s) that control the cooling assemblies 202 and activation (full and partial activations) and deactivation of blocking mechanisms, such as the blocking mechanisms 250.

It should now be understood that embodiments of the present disclosure are directed to cooling assemblies that cool heat generating components having a low pressure drop by utilizing angled fins to produce a pressure difference between alternating converging channels and diverging channels. More particularly, ambient air approaches the angled fins and is allowed to flow through the converging and diverging channels. The converging channels create regions of high pressure, while the diverging channels create regions of low air pressure. These regions of high and low air pressure are fluidly coupled to an internal heat sink comprising an array of internal fins that define an array of internal channels. The pressure difference is leveraged to pump a fraction of air into the internal channels. This redirected air travels within the internal channels from the converging channels and then exits at a diverging channel. The redirected air is brought in close proximity to the heat generating components that are cooled such that the redirected air is warmed up, thereby extracting heat from the internal fins. The warmed redirected air then exits the internal heat sink on the diverging channel sides where it joins the freestream of air that flows through the diverging channel and exits at the backside of the cooling assembly.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

### Example Clauses

Implementation examples are described in the following numbered clauses:
Clause 1: A cooling assembly comprising a plate comprising a surface and a plurality of openings; a plurality of angled fins extending from the plate, wherein the plurality of angled fins define a plurality of channels comprising converging channels and diverging channels; and one or more blocking mechanisms extending from the plate, the one or more blocking mechanisms configured to regulate airflow.
Clause 2: The cooling assembly of Clause 1, wherein the plate further comprises an array of internal fins, wherein the array of internal fins defines an array of internal channels, wherein the array of internal channels is fluidly coupled to the plurality of channels defined by the plurality of angled fins.
Clause 3: The cooling assembly of any of Clauses 1-2, wherein the one or more blocking mechanisms are positioned within at least one channel of the plurality of channels.
Clause 4: The cooling assembly of any of Clauses 1-3, wherein the one or more blocking mechanisms are positioned outside of the plurality of channels.
Clause 5: The cooling assembly of any of Clauses 1-4, wherein the one or more blocking mechanisms are positioned adjacent to at least one converging end of a channel of the plurality of channels.
Clause 6: The cooling assembly of any of Clauses 1-5, wherein each angled fin of the plurality of angled fins is non-orthogonal with respect to an edge of the plate.
Clause 7: The cooling assembly of any of Clauses 1-6, wherein the surface is present on the plate within plurality of channels and the surface defines an opening to expose the array of internal channels within plurality of channels.
Clause 8: The cooling assembly of any of Clauses 1-7, wherein the opening is a rectangular opening along a length of the plate.
Clause 9: The cooling assembly of any of Clauses 1-8, wherein the plurality of angled fins are operable to receive an airflow in an airflow direction; and the airflow and the plurality of angled fins create a high pressure within the converging channels and a low pressure within the diverging channels, wherein the high pressure is greater than the low pressure, wherein the blocking mechanisms are operable to redirect the airflow.
Clause 10: The cooling assembly of any of Clauses 1-9, wherein the high pressure and the low pressure causes air to flow from the converging channels, into the array of internal channels, and into the diverging channels.
Clause 11: The cooling assembly of any of Clauses 1-10, wherein the one or more blocking mechanisms are activatable to obstruct at least a portion of the airflow.
Clause 12: The cooling assembly of any of Clauses 1-11, wherein an activation of the one or more blocking mechanisms causes the one or more blocking mechanisms to extend vertically from the surface or horizontally across the surface to obstruct airflow from at least a portion of a space on the surface.
Clause 13: The cooling assembly of any of Clauses 1-12, wherein at least one of the one or more blocking mechanisms is an attached extension that is configurable to extend from a fin of the plurality of angled fins.
Clause 14: The cooling assembly of any of Clauses 1-13, wherein the one or more blocking mechanisms can be placed in an open configuration or a blocked configuration.
Clause 15: The cooling assembly of any of Clauses 1-14, wherein a combination of the one or more blocking is configurable to place the plate in a bypass configuration, a blocked inlet configuration, a blocked outlet configuration, or an internal flow configuration.
Clause 16: The cooling assembly of any of Clauses 1-15, wherein the array of internal fins define a chevron pattern.
Clause 17: An electronic assembly comprising a plate comprising a first surface, a second surface, and a plurality of openings; a plurality of angled fins extending from the first surface of the plate, wherein the plurality of angled fins define a plurality of channels comprising converging channels and diverging channels; one or more blocking mechanisms extending from the plate, the one or more blocking mechanisms configured to regulate airflow; and one or more electronic devices coupled to the second surface of the plate.
Clause 18: The electronic assembly of Clause 17, wherein the plate further comprises an array of internal fins, wherein the array of internal fins defines an array of internal channels, wherein the array of internal channels is fluidly coupled to the plurality of channels defined by the plurality of angled fins.
Clause 19: The electronic assembly of any of Clauses 17-18, wherein the first surface is present on the plate within the plurality of channels and the first surface defines an opening to expose the array of internal channels within the plurality of channels.
Clause 20: The electronic assembly of any of Clauses 17-19, wherein the plurality of angled fins are operable to receive an airflow in an airflow direction, and the airflow and the plurality of angled fins create a high pressure within the converging channels and a low pressure within the diverging channels, wherein the high pressure is greater than the low pressure, wherein the blocking mechanisms are operable to redirect the airflow.
Clause 21: The electronic assembly of any of Clauses 17-20, wherein the high pressure and the low pressure causes air to flow from the converging channels, into the array of internal channels, and into the diverging channels.
Clause 22: The electronic assembly of any of Clauses 17-21, wherein the one or more blocking mechanisms are positioned within at least one channel of the plurality of channels.
Clause 23: The electronic assembly of any of Clauses 17-22, wherein the one or more blocking mechanisms are positioned outside of the plurality of channels.
Clause 24: The electronic assembly of any of Clauses 17-23, wherein the one or more blocking mechanisms are positioned adjacent to at least one converging end of a channel of the plurality of channels.
Clause 25: The electronic assembly of any of Clauses 17-24, wherein each angled fin of the plurality of angled fins is non-orthogonal with respect to an edge of the plate.
Clause 26: The electronic assembly of any of Clauses 17-25, wherein the surface is present on the plate within the plurality of channels and the surface defines an opening to expose the array of internal channels within the plurality of channels.
Clause 27: The electronic assembly of any of Clauses 17-26, wherein the opening is a rectangular opening along a length of the plate.
Clause 28: The electronic assembly of any of Clauses 17-27, wherein the plurality of angled fins are operable to receive an airflow in an airflow direction; and the airflow and the plurality of angled fins create a high pressure within the converging channels and a low pressure within the diverging channels, wherein the high pressure is greater than the low pressure, wherein the blocking mechanisms are operable to redirect the airflow.
Clause 29: The electronic assembly of any of Clauses 17-28, wherein the high pressure and the low pressure causes air to flow from the converging channels, into the array of internal channels, and into the diverging channels.
Clause 30: The electronic assembly of any of Clauses 17-29, wherein the one or more blocking mechanisms are activatable to obstruct at least a portion of the airflow.
Clause 31: The electronic assembly of any of Clauses 17-30, wherein an activation of the one or more blocking mechanisms causes the one or more blocking mechanisms to extend vertically from the surface or horizontally across the surface to obstruct airflow from at least a portion of a space on the surface.
Clause 32: The electronic assembly of any of Clauses 17-31, wherein at least one of the one or more blocking mechanisms is an attached extension that is configurable to extend from a fin of the plurality of angled fins.
Clause 33: The electronic assembly of any of Clauses 17-32, wherein the one or more blocking mechanisms can be placed in an open configuration or a blocked configuration.
Clause 34: The electronic assembly of any of Clauses 17-33, wherein a combination of the one or more blocking is configurable to place the plate in a bypass configuration, a blocked inlet configuration, a blocked outlet configuration, or an internal flow configuration.
Clause 35: The electronic assembly of any of Clauses 17-34, wherein the array of internal fins define a chevron pattern.
Clause 36: A vehicle comprising a body; and an electronic assembly coupled to the body, the electronic assembly comprising: a plate comprising a first surface, a second surface, and a plurality of openings; a plurality of angled fins extending from the first surface of the plate, wherein the plurality of angled fins define a plurality of channels comprising converging channels and diverging channels; one or more blocking mechanisms extending from the plate, the one or more blocking mechanisms configured to regulate airflow; and one or more electronic devices coupled to the second surface of the plate.
Clause 37: The vehicle of Clause 36, wherein the plate further comprises an array of internal fins, wherein the array of internal fins defines an array of internal channels, wherein the array of internal channels is fluidly coupled to the plurality of channels defined by the plurality of angled fins.
Clause 38: The vehicle of any of Clauses 36-37, wherein the vehicle is an aircraft comprising an electric motor, and the electronic assembly is coupled to the vehicle at the electric motor.
Clause 39: The vehicle of any of Clauses 36-38, wherein the first surface is present on the plate within the plurality of channels and the first surface defines an opening to expose the array of internal channels within the plurality of channels.
Clause 40: The vehicle of any of Clauses 36-39, wherein the opening is a rectangular opening along a length of the plate.
Clause 41: The vehicle of any of Clauses 36-40, wherein the one or more blocking mechanisms are positioned within at least one channel of the plurality of channels.
Clause 42: The vehicle of any of Clauses 36-41, wherein the one or more blocking mechanisms are positioned outside of the plurality of channels.
Clause 43: The vehicle of any of Clauses 36-42, wherein the one or more blocking mechanisms are positioned adjacent to at least one converging end of a channel of the plurality of channels.
Clause 44: The vehicle of any of Clauses 36-43, wherein each angled fin of the plurality of angled fins is non-orthogonal with respect to an edge of the plate.
Clause 45: The vehicle of any of Clauses 36-44, wherein the plurality of angled fins are operable to receive an airflow in an airflow direction; and the airflow and the plurality of angled fins create a high pressure within the converging channels and a low pressure within the diverging channels, wherein the high pressure is greater than the low pressure, wherein the blocking mechanisms are operable to redirect the airflow.
Clause 46: The vehicle of any of Clauses 36-45, wherein the high pressure and the low pressure causes air to flow from the converging channels, into the array of internal channels, and into the diverging channels.
Clause 47: The vehicle of any of Clauses 36-46, wherein the one or more blocking mechanisms are activatable to obstruct at least a portion of the airflow.
Clause 48: The vehicle of any of Clauses 36-47, wherein an activation of the one or more blocking mechanisms causes the one or more blocking mechanisms to extend vertically from the surface or horizontally across the surface to obstruct airflow from at least a portion of a space on the surface.
Clause 49: The vehicle of any of Clauses 36-48, wherein at least one of the one or more blocking mechanisms is an attached extension that is configurable to extend from a fin of the plurality of angled fins.
Clause 50: The vehicle of any of Clauses 36-49, wherein the one or more blocking mechanisms can be placed in an open configuration or a blocked configuration.
Clause 51: The vehicle of any of Clauses 36-50, wherein a combination of the one or more blocking is configurable to place the plate in a bypass configuration, a blocked inlet configuration, a blocked outlet configuration, or an internal flow configuration.
Clause 52: The vehicle of any of Clauses 36-51, wherein at least one of the bypass configuration, the blocked inlet configuration, the blocked outlet configuration, or the internal flow configuration is utilized during one or more of take-off, coasting, or landing modes of the vehicle.
Clause 53: The vehicle of any of Clauses 36-52, wherein the array of internal fins defines a chevron pattern.
Clause 54: One or more processing systems, comprising: one or more memories comprising computer-executable instructions; and one or more processors configured to execute the computer-executable instructions and cause the one or more processing systems to perform a method in accordance with any one of Clauses 1-53.
Clause 55: One or more processing systems, comprising means for performing a method in accordance with any one of Clauses 1-53.
Clause 56: One or more non-transitory computer-readable media comprising instructions that, when executed by one or more processors of a computing system, cause the computing system to perform the operations of any one of Clauses 1-53.
Clause 57: One or more computer program products embodied on one or more computer-readable storage media comprising code for performing a method in accordance with any one of Clauses 1-53.

### Additional Considerations

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, unless stated otherwise, the term “or” is used in an inclusive sense. This inclusive usage of or is equivalent to “and/or”. Thus, when options are delineated using “or” it permits the selection of one or more of the enumerated options concurrently. For example, if the document stipulates that a component may comprise option A or option B, it shall be understood to mean that the component may comprise option A, option B, or both option A and option B, and does not mean, unless stated expressly that the component includes either option A or option B. This inclusive interpretation ensures that all potential combinations of the options are permissible, rather than restricting the choice to a singular, exclusive option.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. §112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A cooling assembly comprising:
a plate comprising a surface and a plurality of openings;
a plurality of angled fins extending from the plate, wherein the plurality of angled fins define a plurality of channels comprising converging channels and diverging channels; and
one or more blocking mechanisms extending from the plate, the one or more blocking mechanisms configured to regulate airflow.

2. The cooling assembly of claim 1, wherein the plate further comprises an array of internal fins, wherein the array of internal fins defines an array of internal channels, wherein the array of internal channels is fluidly coupled to the plurality of channels defined by the plurality of angled fins.

3. The cooling assembly of claim 1, wherein the one or more blocking mechanisms are positioned within at least one channel of the plurality of channels.

4. The cooling assembly of claim 1, wherein the one or more blocking mechanisms are positioned outside of the plurality of channels.

5. The cooling assembly of claim 4, wherein the one or more blocking mechanisms are positioned adjacent to at least one converging end of a channel of the plurality of channels.

6. The cooling assembly of claim 1, wherein each angled fin of the plurality of angled fins is non-orthogonal with respect to an edge of the plate.

7. The cooling assembly of claim 2, wherein the surface is present on the plate within plurality of channels and the surface defines an opening to expose the array of internal channels within plurality of channels.

8. The cooling assembly of claim 7, wherein the opening is a rectangular opening along a length of the plate.

9. The cooling assembly of claim 2, wherein:
the plurality of angled fins are operable to receive an airflow in an airflow direction; and
the airflow and the plurality of angled fins create a high pressure within the converging channels and a low pressure within the diverging channels, wherein the high pressure is greater than the low pressure, wherein the blocking mechanisms are operable to redirect the airflow.

10. The cooling assembly of claim 9, wherein the high pressure and the low pressure causes air to flow from the converging channels, into the array of internal channels, and into the diverging channels.

11. The cooling assembly of claim 9, wherein the one or more blocking mechanisms are activatable to obstruct at least a portion of the airflow.

12. The cooling assembly of claim 1, wherein an activation of the one or more blocking mechanisms causes the one or more blocking mechanisms to extend vertically from the surface or horizontally across the surface to obstruct airflow from at least a portion of a space on the surface.

13. The cooling assembly of claim 1, wherein at least one of the one or more blocking mechanisms is an attached extension that is configurable to extend from a fin of the plurality of angled fins.

14. The cooling assembly of claim 1, wherein the one or more blocking mechanisms can be placed in an open configuration or a blocked configuration.

15. The cooling assembly of claim 1, wherein a combination of the one or more blocking is configurable to place the plate in a bypass configuration, a blocked inlet configuration, a blocked outlet configuration, or an internal flow configuration.

16. The cooling assembly of claim 2, wherein the array of internal fins defines a chevron pattern.

17. An electronic assembly comprising:
a plate comprising a first surface, a second surface, and a plurality of openings;
a plurality of angled fins extending from the first surface of the plate, wherein the plurality of angled fins define a plurality of channels comprising converging channels and diverging channels;
one or more blocking mechanisms extending from the plate, the one or more blocking mechanisms configured to regulate airflow; and
one or more electronic devices coupled to the second surface of the plate.

18. A vehicle comprising:
a body; and
an electronic assembly coupled to the body, the electronic assembly comprising:
a plate comprising a first surface, a second surface, and a plurality of openings
a plurality of angled fins extending from the first surface of the plate, wherein the plurality of angled fins define a plurality of channels comprising converging channels and diverging channels;
one or more blocking mechanisms extending from the plate, the one or more blocking mechanisms configured to regulate airflow; and
one or more electronic devices coupled to the second surface of the plate.

19. The vehicle of claim 18, wherein the plate further comprises:
an array of internal fins, wherein the array of internal fins defines an array of internal channels, wherein the array of internal channels is fluidly coupled to the plurality of channels defined by the plurality of angled fins.

20. The vehicle of claim 18, wherein the vehicle is an aircraft further comprising:
one or more electronic control units to control functions of the electronic assembly, wherein the functions comprise partial activation, full activation, or deactivation of the one or more blocking mechanisms; and
an electric motor, and the electronic assembly is coupled to the vehicle at the electric motor.
